(19) United States
(12) Patent Application Publication
(10) Pub. No.: US 2019/0292381 A1
(43) Pub. Date: Sep. 26, 2019

(54) CONDUCTIVE COATING MATERIAL AND PRODUCTION METHOD FOR SHIELDED PACKAGE USING CONDUCTIVE COATING MATERIAL

(71) Applicant: TATSUTA ELECTRIC WIRE & CABLE CO., LTD., Higashiosaka-shi, Osaka (JP)

(72) Inventors: Hajime Nakazono, Kizugawa-shi (JP); Hiroaki Umeda, Kizugawa-shi (JP); Kazuhiro Matsuda, Kizugawa-shi (JP); Ken Yukawa, Kizugawa-shi (JP)

(73) Assignee: TATSUTA ELECTRIC WIRE & CABLE CO., LTD., Higashiosaka-shi, Osaka (JP)

(21) Appl. No.: 16/316,717

(22) PCT Filed: Feb. 22, 2017
(86) PCT No.: PCT/JP2017/006475

§ 371 Date: Jan. 10, 2019

(30) Foreign Application Priority Data
Jul. 14, 2016 (JP) 2016-139566

(51) Int. Cl. C09D 5/24; C09D 163/00; H01L 21/56; H01L 23/552; H01L 21/78; H01L 21/3205

(52) U.S. Cl. CPC C09D 5/24; C09D 163/00; H01L 21/561; C08K 2003/0806; H01L 21/78; H01L 21/32056; H01L 23/552

(57) ABSTRACT

A conductive coating material includes at least (A) 100 parts by mass of binder component containing 5 to 30 parts by mass of solid epoxy resin which is a solid at normal temperature and 20 to 90 parts by mass of liquid epoxy resin which is a liquid at normal temperature; (B) 500 to 1800 parts by mass of metal particles; and (C) 0.3 to 40 parts by mass of hardener, in which the metal particles include (a) spherical metal particles and (b) flaky metal particles, a mass ratio of (a) the spherical metal particles to (b) the flaky metal particles is 25:75 to 75:25 (in terms of (a):(b)), and a viscosity at a liquid temperature of 25° C. of the conductive coating material is 100 to 600 m Pa·s when measured at rotation speed of 0.5 rpm with a cone-plate rotary viscometer.

### TECHNICAL FIELD

The present invention relates to a conductive coating material and a production method for a shielded package using the conductive coating material.

### BACKGROUND ART

In recent years, in electronic devices such as portable telephones and tablet terminals, a lot of electronic parts for wireless communication to transmit high-volume data have been mounted. Such electronic parts for wireless communication have a problem in that the electronic parts not only easily generate noises but also are highly sensitive to noises, and, when exposed to noises from outside, the electronic parts are easily caused to carry out erroneous operations.

Meanwhile, in order to obtain miniaturization and weight reduction as well as high functions of electronic devices, it is required to increase mounting density of electronic parts. However, when the mounting density is increased, there occurs a problem in that not only electronic parts as sources for generating noises are increased but also electronic parts affected by the noises are increased.

In the related art, as means for solving the problem, a so-called shielded package that prevents generation of noises from an electronic part and prevents penetration of noises by covering the electronic part which is a source for generating noises with a shield layer for each package is known. For example, PTL 1 discloses that it is possible to easily obtain an electromagnetic shielded member with a high shielding effect by spraying a conductive or semi-conductive material on a surface of a package and coating thereof. However, in a case where a shield layer is formed by spray coating using a solution made of metal particles and a solvent, there is a problem in that excellent shielding properties are not obtained and adhesion between the shield layer and a package deteriorates.

In addition, as means for efficiently preparing a shielded package, for example, as disclosed in PTL 2, a method of producing a circuit module is known, which includes a step of covering a plurality of ICs with an insulating layer, a step of covering the insulating layer with a shield layer made of a conductive paste, and a step of dividing a substrate in which the shield layer is formed (method of preliminarily forming a cut groove, of which a tip end portion has a smaller width than that of a base end portion in a depth direction, on the insulating layer before forming a shield layer for covering the insulating layer, forming a shield layer by coating a conductive resin to be filled in the cut groove, and then dividing a substrate by cutting away thereof with a width that is larger than the width of the tip end portion and smaller than the width of the base end portion along the tip end portion of the cut groove). As disclosed in the document, examples of a method for forming a shield layer include a transfer mold method or potting method, a vacuum printing method, and the like. However, all of these methods require large-scale equipment and have a problem in that it is easy to entrain bubbles when a conductive resin is filled in a groove portion.

As means for solving the above-described problem, for example, PTL 3 suggests, as a conductive coating material for a shielded package, those containing at least (B) 200 to 1800 parts by mass of metal particles and (C) 0.3 to 40 parts by mass of hardener, with respect to 100 parts by mass of binder component (A) containing an epoxy resin which is a solid at normal temperature (hereinafter, may be referred to as “solid epoxy resin”) and an epoxy resin which is liquid at normal temperature (hereinafter, may be referred to as “liquid epoxy resin”).

### CITATION LIST

### Patent Literature

[PTL 1] JP-A-2003-258137

[PTL 2] JP-A-2008-42152

[PTL 3] Pamphlet of International Publication No. WO 2016/051700

### SUMMARY OF INVENTION

### Technical Problem

However, the conductive coating material disclosed in PTL 3 has room for further improvement concerning connection stability between a ground circuit and a conductive coating material.

The present invention is made in view of the above matters, and an object of the present invention is to provide a conductive coating material which can give a shield layer by spray coating, whose shielding properties, adhesion between a ground circuit and the conductive coating material and connection stability between the same are excellent. In addition, another object of the present invention is to provide a production method for a shielded package in which the above-described shield layer can be easily formed.

### Solution to Problem

In view of the above matters, a conductive coating material of the present invention contains at least (A) 100 parts by mass of binder component containing 5 to 35 parts by mass of solid epoxy resin which is a solid at normal temperature and 20 to 90 parts by mass of liquid epoxy resin which is a liquid at normal temperature in a range not exceeding 100 parts by mass in total, (B) 500 to 1800 parts by mass of metal particles, and (C) 0.3 to 40 parts by mass of hardener, in which the metal particles include (a) spherical metal particles and (b) flaky metal particles, and a mass ratio of (a) the spherical metal particles to (b) the flaky metal particles is 25:75 to 75:25 (in terms of (a):(b)), and a viscosity at a liquid temperature of 25° C. of the conductive coating material is 100 to 600 m Pa·s when measured at rotation speed of 0.5 rpm with a cone-plate rotary viscometer.

The liquid epoxy resin preferably contains 5 to 35 parts by mass of liquid glycidyl amine-based epoxy resin and 20 to 55 parts by mass of liquid glycidyl ether-based epoxy resin so as not to exceed 90 parts by mass in total.

The liquid glycidyl amine-based liquid epoxy resin preferably has 80 to 120 g/eq of epoxy equivalent and 1.5 Pa·s or less of viscosity, and the liquid glycidyl ether-based epoxy resin preferably has 180 to 220 g/eq of epoxy equivalent and 6 Pa·s or less of viscosity.

In the above conductive coating material, the above-described (A) binder component can further contain a (meth)acrylate compound.

The conductive coating material is suitably used for shielding a package of an electronic parts.

According to the present invention, a production method for a shielded package in which electronic parts are mounted on a substrate, and a package obtained by sealing the electronic parts with a sealing material is covered with a shield layer, includes at least a step of mounting a plurality of electronic parts on a substrate and sealing the electronic parts by filling the substrate with a sealing material and hardening the sealing material; a step of forming a groove portion by cutting away the sealing material between the plurality of electronic parts and individualizing a package of each electronic part on the substrate by the groove portion; a step of coating a conductive coating material according to the present invention by spraying on a substrate on which the individualized package is formed; a step of forming a shield layer by heating the substrate on which the conductive coating material is coated and hardening the conductive coating material; and a step of obtaining an individualized shielded package by cutting the substrate, on which the shield layer is formed, along the groove portion.

### Advantageous Effects of Invention

According to the conductive coating material of the present invention, by spray coating the surface of the package, it is possible to easily form a shield layer which is excellent in a shielding effect, adhesion between the ground circuit and the conductive coating material, and connection stability.

In addition, according to the production method for a shielded package of the present invention, it is possible to efficiently provide a shielded package excellent in the shielding property, the adhesion between the ground circuit and the conductive coating material, and the connection stability without using a large-scaled apparatus.

### BRIEF DESCRIPTION OF DRAWINGS

FIG. 1 is a schematic sectional view illustrating an embodiment of a production method for a shielded package.

FIG. 2 is a plan view illustrating an example of the shielded package before being individualized.

FIG. 3 is a schematic sectional view illustrating a chip sample subjected to a connection stability test between a ground circuit and a conductive coating material.

### DESCRIPTION OF EMBODIMENTS

As described above, the conductive coating material according to the present invention contains at least (B) 500 to 1800 parts by mass of metal particles and (C) 0.3 to 40 parts by mass of hardener, with respect to 100 parts by mass of binder component (A) containing an epoxy resin which is solid at normal temperature (hereinafter, may be referred to as “solid epoxy resin”) and an epoxy resin which is liquid at normal temperature (hereinafter, may be referred to as “liquid epoxy resin”). Although the application of the conductive coating material is not particularly limited, the conductive coating material is suitably used to obtain a shielded package by forming a shield layer by being sprayed onto the surface of the package before being individualized or the individualized package.

The binder component in the conductive coating material of the present invention contains an epoxy resin as an essential component, and can further contain a (meth)acrylate compound as necessary.

Here, the “solid at normal temperature” means that the epoxy resin does not have fluidity at 25° C. in a solvent-free state, and “liquid at normal temperature” means that the epoxy resin has the fluidity in the same condition. The solid epoxy resin is preferably 5 to 30 parts by mass, and is more preferably 5 to 20 parts by mass, with respect to 100 parts by mass of binder component. In addition, the liquid epoxy resin is preferably 20 to 90 parts by mass, and is more preferably 25 to 80 parts by mass, with respect to 100 parts by mass of binder component.

By using the epoxy resin which is solid at normal temperature, it is possible to obtain the conductive coating material which is capable of forming a shield layer without unevenness by being uniformly applied to the surface of the package. The solid epoxy resin preferably has two or more glycidyl groups in the molecule and has an epoxy equivalent of 150 to 280 g/eq. When the epoxy equivalent is 150 g/eq or more, problems such as cracks and warpage are less likely to occur, and when the epoxy equivalent is 280 g/eq or less, a coating film having more excellent heat resistance is easily obtained.

The solid epoxy resin can be used by being dissolved in a solvent. The solvent to be used is not particularly limited and can be appropriately selected from those described later.

The solid epoxy resin is not particularly limited, but specific examples thereof include a bisphenol type epoxy resin such as a bisphenol A type epoxy resin, a bisphenol F type epoxy resin, and a bisphenol S type epoxy resin; a spirocyclic epoxy resin; a naphthalene type epoxy resin; a biphenyl type epoxy resin; a terpene type epoxy resin; a glycidyl ether type epoxy resin such as tris(glycidyloxyphenyl) methane, and tetrakis(glycidyloxyphenyl) ethane; a glycidyl amine-based epoxy resin such as tetraglycidyl diamino diphenyl methane; a tetrabromobisphenol A type epoxy resin; a novolac type epoxy resin such as a cresol novolak type epoxy resin, a phenol novolak type epoxy resin, an α-naphthol novolac type epoxy resin, and a brominated phenol novolak type epoxy resin; and a rubber-modified epoxy resin. These can be used alone or two or more kinds thereof may be used in combination.

As described above, 20 to 90 parts by mass of the epoxy resin which is liquid at normal temperature is used with respect to 100 parts by mass of the binder component, and 5 to 35 parts by mass of which is preferably a liquid glycidyl amine-based epoxy resin, and 20 to 55 parts by mass is more preferably a liquid glycidyl ether-based epoxy resin. In a case where the liquid glycidyl amine-based epoxy resin and the liquid glycidyl ether-based epoxy resin are used in combination within this blending amount range, the conductivity and adhesion of the conductive coating material are excellent in a well-balanced manner, warpage of the hardened coating film is less likely to occur, and thereby the shielded package having more excellent heat resistance can be obtained.

The liquid glycidyl amine-based liquid epoxy resin preferably has 80 to 120 g/eq of epoxy equivalent and 1.5 Pa*s or less of viscosity and more preferably has 0.5 to 1.5 Pa·s, and the liquid glycidyl ether-based epoxy resin preferably has 180 to 220 g/eq of epoxy equivalent and 6 Pa·s or loess of viscosity, and has more preferably 1 to 6 Pa·s. In a case where a liquid glycidyl amine-based epoxy resin and a liquid glycidyl ether-based epoxy resin having epoxy equivalents and viscosities within the above preferable ranges are used, it is possible to obtain a shielded package in which warpage of the coating film after hardening is further reduced, the heat resistance is more excellent, and the coating film thickness becomes more uniform.

Here, the viscosity of the liquid glycidyl amine-based liquid epoxy resin is a value measured at a liquid temperature of 25° C. with a BH type viscometer (rotor No. 5, rotation speed of 10 rpm).

The (meth)acrylate compound that can be used in the present invention is an acrylate compound or a methacrylate compound, and is not particularly limited as long as it is a compound having an acryloyl group or a methacryloyl group. Examples of the (meth)acrylate compound include isoamyl acrylate, neopentyl glycol diacrylate, trimethylolpropane triacrylate, ditrimethylolpropane tetraacrylate, 2-hydroxy-3-acryloyloxypropyl methacrylate, a phenyl glycidyl ether acrylate hexamethylene diisocyanate urethane prepolymer, a bisphenol A diglycidyl ether acrylic acid adduct, ethylene glycol dimethacrylate, and diethylene glycol dimethacrylate. These can be used alone or two or more kinds thereof may be used in combination.

In a case where the (meth)acrylate compound is used as described above, the blending ratio (“% by mass” in a case where the total amount of both is 100%) of the epoxy resin to the (meth)acrylate compound is preferably 5:95 to 95:5, and more preferably 20:80 to 80:20. When the content of the (meth)acrylate compound is 5% by mass or more, the storage stability of the conductive coating material is excellent, the conductive coating material can be quickly hardened, and it is possible to prevent sagging of the coating material during hardening. In addition, in a case where the (meth)acrylate compound is 95% by mass or less, the adhesion between the package and the shield layer is likely to be excellent.

In addition to the epoxy resin and the (meth)acrylate compound, an alkyd resin, a melamine resin, a xylene resin, or the like can be added as a modifying agent to the binder component for the purpose of improving physical properties of the conductive coating material.

A content ratio in a case of blending a modifying agent to the binder component is preferably 40% by mass or less, and more preferably 100/% by mass or less with respect to the binder component, from a viewpoint of adhesion between the shield layer and the package.

In the present invention, a hardener for hardening the binder component is used. The hardener is not particularly limited, but examples thereof include a phenol-based hardener, an imidazole-based hardener, an amine-based hardener, a cation-based hardener, a radical-based hardener, and the like. These can be used alone or two or more kinds thereof may be used in combination.

Examples of the phenol-based hardener include a novolac phenol-based compound and a naphthol-based compound.

Examples of the imidazole-based hardener include imidazole, 2-undecyl imidazole, 2-heptadecyl imidazole, 2-methyl imidazole, 2-ethyl imidazole, 2-phenyl imidazole, 2-ethyl-4-methyl-imidazole, 1-cyanoethyl-2-undecyl imidazole, and 2-phenyl imidazole.

Examples of the cation-based hardener include an onium-based compound represented by an amine salt of boron trifluoride, P-methoxybenzene diazonium hexafluorophosphate, diphenyl iodonium hexafluorophosphate, triphenyl sulfonium, tetra-n-butyl phosphonium tetraphenyl borate, and tetra-n-butyl phosphonium-o,o-diethyl phosphorodithioate.

Examples of the radical-based hardener (polymerization initiator) include di-cumyl peroxide, t-butyl cumyl peroxide, t-butyl hydroperoxide, and cumene hydroperoxide.

The blending amount of the hardener varies depending on the kind of the hardener, and is usually preferably 0.3 to 40 parts by mass, and is more preferably 0.5 to 35 parts by mass, with respect to 100 parts by mass of the total amount of the binder component. When the blending amount of the hardener is 0.3 parts by mass or more, the adhesion between the shield layer and the surface of the package and the conductivity of the shield layer become excellent and a shield layer having an excellent shielding effect is easily obtained, and when the blending amount of the hardener is 40 parts by mass or less, the storage stability of the conductive coating material can be kept favorably.

In the coating material of the present invention, known additives such as a defoaming agent, a thickener, a pressure sensitive adhesive, a filler, a flame retardant, and a coloring agent, can be added within a range not to impair the object of the invention.

The metal particles that can be used in the present invention are not particularly limited as long as those have conductivity, and examples thereof include copper particles, silver particles, nickel particles, silver-coated copper particles, gold-coated copper particles, silver-coated nickel particles, gold-coated nickel particles, and the like.

Further, as the shape of the metal particles, spherical and flaky (scale-like) metal particles are essential components, and dendritic metal particles or fibrous metal particles can be used in combination as necessary. The spherical shape includes a substantially spherical shape such as a substantially polyhedral sphere (reduced powder) and an indefinite shape (electrolytic powder), in addition to a substantially perfect sphere (atomized powder).

A proportion of the total content of the spherical and flaky metal particles in the entire amount of the metal particles is not particularly limited, but is preferably 40% to 100% by mass, is more preferably 60% to 100% by mass, and is still more preferably 80% to 100% by mass.

The blending amount of (the total amount of the metal particles having a spherical shape, a flaky shape, and other shapes) the metal particles is preferably 500 to 1800 parts by mass, and is more preferably 550 to 1800 parts by mass, with respect to 100 parts by mass of the binder component. When the blending amount of the metal particles is 500 parts by mass or more, the conductivity of the shield layer becomes excellent, and when the amount thereof is 1,800 parts by mass or less, the adhesion between the shield layer and the package and the physical properties of the conductive coating material after hardening become excellent, and the shield layer is less likely to crack when being cut with a dicing saw as described below.

In addition, an average particle diameter of the metal particles is preferably 1 to 30 μm in both of the spherical and flaky metal particles. When the average particle diameter of the metal particles is 1 μm or more, the dispersibility of the metal particles becomes excellent, aggregation can be prevented, and oxidation is hard to occur, and when the average particle diameter of the metal particles is 30 μm or less, connectivity with the ground circuit of the package becomes excellent.

Here, in this specification, the average particle diameter means the particle diameter of the average particle diameter D50 (median diameter) based on the number measured by a laser diffraction/scattering method.

In addition, a tap density of the flaky metal particles is not particularly limited, and is preferably 4.0 to 6.0 g/cm³. When the tap density is within the above range, the conductivity of the shield layer becomes excellent.

In addition, an aspect ratio of the flaky metal particles is not particularly limited, and is preferably 5 to 20, and is more preferably 5 to 10. If the aspect ratio is in the above-described range, conductivity of a shield layer is more favorable.

In a case where the total amount of (a) the spherical metal particles and (b) the flaky metal particles is set to 100% by mass, the mass ratio ((a):(b)) of both particles is 25:75 to 75:25, and is preferably 25:75 to 60:40. When the mass ratio is within the above range, it is possible to obtain the conductive coating material excellent in the connection stability and shielding properties.

Since the conductive coating material of the present invention is uniformly applied to the surface of the package by spraying, it is preferable that the conductive coating material has a lower viscosity than that of a so-called conductive paste.

That is, the viscosity of the conductive coating material of the present invention at a liquid temperature of 25° C. is 100 to 600 mPa·s, and is preferably 150 to 500 mPa·s, and is more preferably 200 to 500 mPa·s when measured at rotation speed of 0.5 rpm with a cone-plate rotary viscometer. When the viscosity is 100 mPa·s or more, it is possible to form the shield layer uniformly by preventing the liquid sagging on the wall surface of the package and to prevent sedimentation of the metal particles. When the viscosity is 600 mPa·s or less, a spray nozzle is prevented from being clogged, and thus it is easy to form a shield layer on the surface of the package and the side wall surface.

The viscosity of the conductive coating material varies depending on the viscosity of the binder component, the blending amount of the metal particles, and the like, and thus a solvent can be used in order to set the viscosity within the above range. The solvent that can be used in the present invention is not particularly limited, and examples thereof include methyl ethyl ketone, acetone, methyl ethyl ketone, acetophenone, methyl cellosolve, methyl cellosolve acetate, methyl carbitol, diethylene glycol dimethyl ether, tetrahydrofuran, methyl acetate, 1-methoxy-2-propanol, and 3-methoxy-3-methyl-1-butyl acetate. These can be used alone or two or more kinds thereof may be used in combination.

The blending amount of the solvent is appropriately adjusted so that the viscosity of the conductive coating material is set to be within the above range. Therefore, although the blending amount of the solvent varies depending on the viscosity of the binder component, the blending amount of the metal particles, and the like, as a guide, it is about 20 to 600 parts by mass with respect to 100 parts by mass of the binder component.

The shield layer obtained by the conductive coating material of the present invention is excellent in the adhesion and connection stability with the ground circuit formed of a copper foil or the like. Specifically, the adhesion between the copper foil of the ground circuit exposed from a part of the shielded package and the shield layer and the connection stability are excellent, and thus the shielding properties of the shielded package on which the shield layer is formed by coating the surface of the shielded package with the conductive coating material become excellent as well.

As the adhesion between the conductive coating material and the copper foil, the shear strength measured according to JIS K 6850:1999 is preferably 3.0 MPa or more. When the shear strength is 3.0 MPa or more, it is possible to prevent the shield layer from peeling from the ground circuit due to impact when cutting the package before being individualized.

The volume resistivity of the shield layer formed of the conductive coating material of the present invention is preferably 10×10⁻⁵ Ω·cm or less from the viewpoint of obtaining the excellent shielding properties.

Next, an embodiment of a method for obtaining a shielded package using the conductive coating material of the present invention will be described with reference to the drawings.

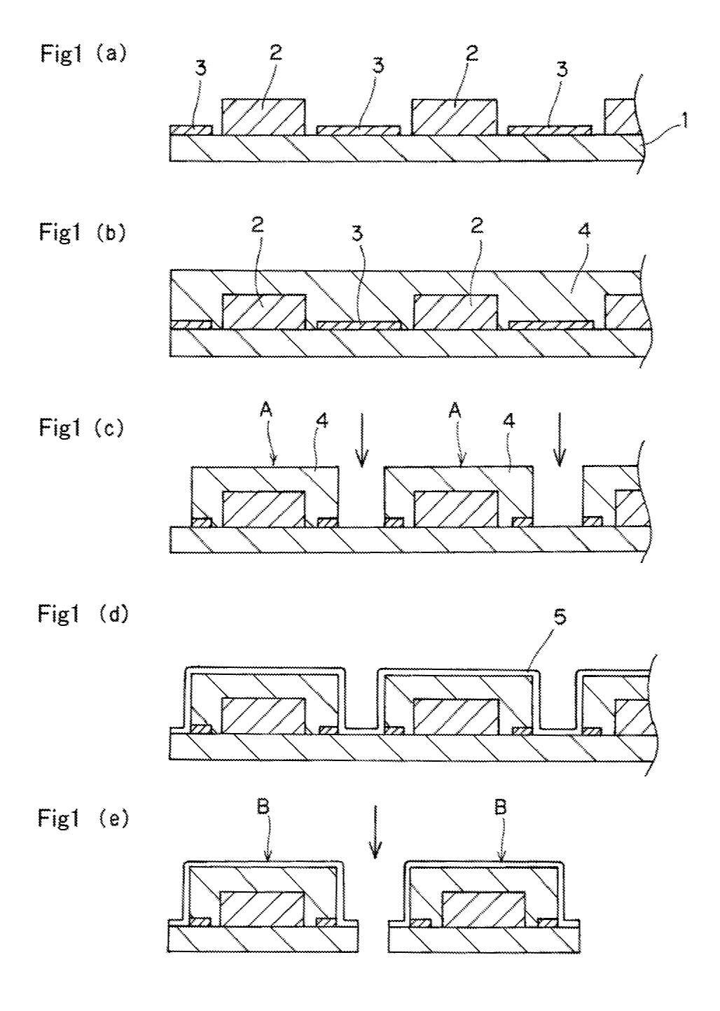

First, as illustrated in FIG. 1(a), a device in which a plurality of electronic parts (IC and the like) 2 are mounted on a substrate 1 and a ground circuit pattern (copper foil) 3 is provided between the plurality of electronic parts 2 is prepared.

Next, as illustrated in FIG. 1(b), the electronic part 2 and the ground circuit pattern 3 are filled with a sealing material 4 and the sealing material is hardened so as to seal the electronic part 2.

Next, as indicated by arrows in FIG. 1(c), the sealing material 4 is cut between the plurality of electronic parts 2 so as to form groove portions, and the packages of the respective electronic parts of the substrate 1 are individualized by these groove portions. Reference numeral A indicates an individualized package. At least a part of the ground circuit is exposed from the wall surface constituting the groove, and the bottom of the groove does not penetrate completely through the substrate.

Meanwhile, predetermined amounts of the binder component, the metal particles, and the hardener described above and the solvent and the modifying agent used as necessary are mixed so as to prepare a conductive coating material.

Next, the conductive coating material is sprayed in a mist form by a known spray gun or the like, and it is uniformly coated on the surface of the package. An injection pressure and an injection flow rate at this time, and the distance between an injection port of the spray gun and the surface of the package are appropriately set as necessary.

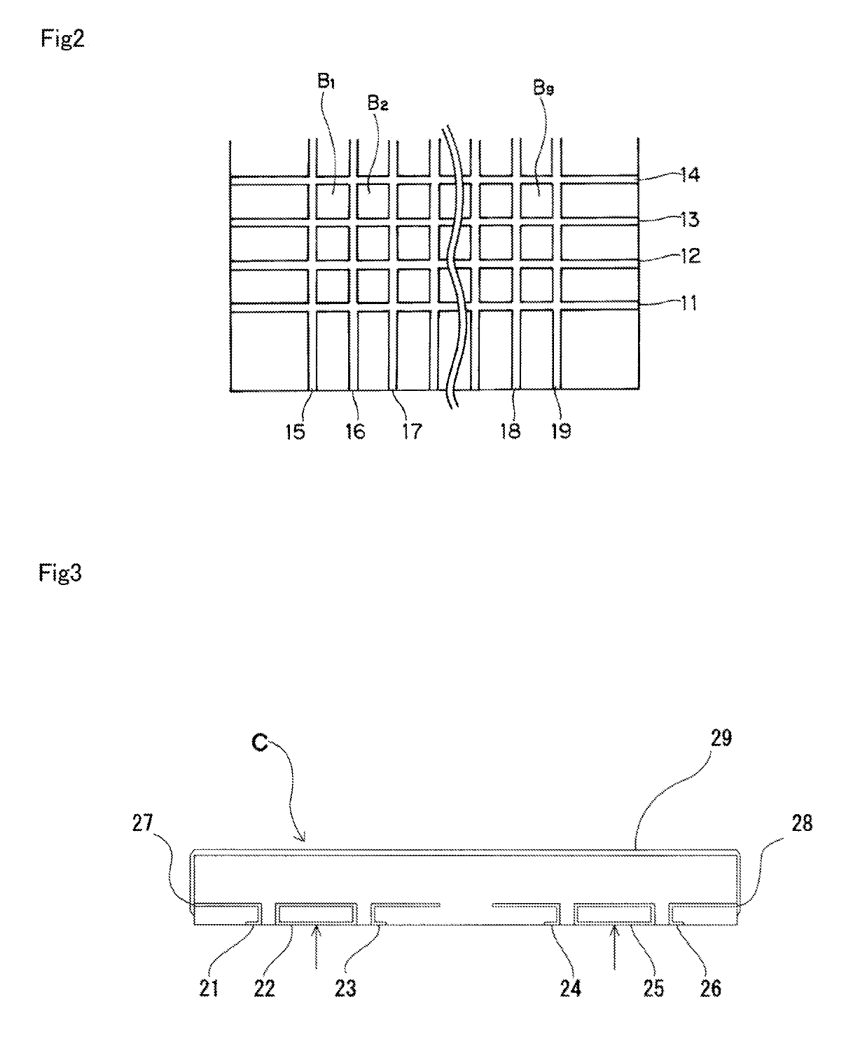

Next, after the package coated with the conductive coating material is heated to sufficiently dry the solvent, the package is further heated to sufficiently harden the (meth)acrylate compound and the epoxy resin in the conductive coating material such that a shield layer (conductive coating film) 5 is formed on the surface of the package as illustrated in FIG. 1(d). The heating conditions at this time can be appropriately set. FIG. 2 is a plan view illustrating the substrate in this state. Reference numerals B1, B2, . . . , and B9 denote the shielded packages before being individualized, and reference numerals 11 to 19 denote grooves between these shielded packages.

Next, as indicated by arrows in FIG. 1(e), the substrate is cut along the bottom of the groove of the package before individualized by a dicing saw or the like so as to obtain an individualized package B.

Since the uniform shield layer is formed on the surface of the package (a top surface portion, a side surface portion, and a corner portion of the boundary between the top surface portion and the side surface portion) of the individualized package B obtained in this way, the excellent shielding properties can be obtained. In addition, since the adhesion between the shield layer and the surface of the package, and that between the shield layer and the ground circuit are excellent, it is possible to prevent the shield layer from peeling from the surface of the package and the ground circuit due to the impact when the package is individualized by a dicing saw or the like.

### EXAMPLES

Hereinafter, the content of the present invention will be specifically described based on examples, but the present invention is not limited to the following examples. In the following description, “part” or “%” is defined as mass basis unless otherwise specified.

### 1. Preparation and Evaluation of Conductive Coating Material

### Example 1

15 parts by mass of solid epoxy resin (trade name “JER 157870” prepared by Mitsubishi Chemical Corporation) and 35 parts by mass of liquid epoxy resin (remark: 10 parts by mass of glycidyl amine-based epoxy resin (trade name “EP-3905S” prepared by ADEKA Corporation), 25 parts by mass of glycidyl ether-based epoxy resin (trade name “EP-4400” prepared by ADEKA Corporation)), and 50 parts by mass of 2-hydroxy-3-acryloyloxypropyl methacrylate (trade name “Light Ester G-201P” prepared by KYOEISHA CHEMICAL Co., Ltd.) were used as binder components in total of 100 parts by mass. Further, 5 parts by mass of 2-methyl imidazole (trade name “2MZ-H”, prepared by Shikoku Chemicals Corporation) and 15 parts by mass of phenol novolak (trade name “Tamanol 758”, prepared by Arakawa Chemical Industries, Ltd.) were used as hardeners, 1-methoxy-2-propanol (PGME) was used as a solvent, and a spherical reduced silver powder having an average particle diameter of 2 μm and a flaky silver powder having an average particle diameter of 5 μm (aspect ratio of 5) were used as metal particles. These were mixed in the blending amount indicated in Table 1 so as to obtain a conductive coating material. The viscosity of the conductive coating material (at liquid temperature 25° C.) was measured with a cone-plate rotary viscometer (rotor CP 40, rotation speed: 0.5 rpm) and the result was 183 mPa·s.

### [Examples 2 to 7], [Comparative Examples 1 to 6]

A conductive coating material was obtained in the same manner as in Example 1 except that the binder component, the hardener, the solvent and the metal particles were blended as indicated in Table 1 and, in Examples 6 and 7, a spherical atomized silver powder (average particle diameter of 5 μm) and a spherical electrolytic silver powder (average particle diameter of 10 μm) were used as spherical metal particles. The viscosity of the obtained conductive coating material was measured in the same manner as in Example 1. The measured viscosity is indicated in Table 1.

The conductive coating material of the above examples and comparative examples were evaluated as follows. The results are indicated in Table 1.

(1) Conductivity of Conductive Coating Film

The conductivity of conductive coating film manufactured by using the conductive coating material of Example 1 was evaluated by volume resistivity. The measurement of the volume resistivity was carried out by attaching a polyimide film having a thickness of 55 μm provided with a slit having a width of 5 mm on a glass epoxy substrate to prepare a printing plate, the conductive coating material obtained in Examples 1 to 7 and Comparative Examples 1 to 6 were spray coated (length: 60 mm, width: 5 mm, and thickness: about 10 μm) under the following spraying conditions, after performing preliminary heating at 80° C. for 60 minutes, the film was heated for 20 minutes at 160° C. to perform a main hardening, and then the polyimide film was peeled off. For this hardened sample, the volume resistivity at both ends was measured by using a tester and the volume resistivity was calculated from the cross-sectional area (S, cm²) and the length (L, cm) according to the following Expression (1).

[Expression 1]

Volume resistivity=S/L×R (1)

<Spray Conditions>

Spray gun: LPH-101A-144LVG manufactured by ANEST IWATA Corporation

Air volume: 200 L/min

Coating time: 9 seconds

Supply pressure: 0.5 MPa

Temperature of surface of the package: 25° C.

Distance from surface of package to nozzle: Approximately 20 cm

Conductive hardening condition: Leave for 20 minutes in a dryer at 160° C.

The cross-sectional area, the length, and the volume resistivity of the sample were determined by forming 15 linear conductive coating films in total such that five linear conductive coating films are formed on each of three glass epoxy substrates, and the average value was calculated. Note that, when the volume resistivity is 10×10⁻⁵ Ω·cm or lower, the conductive coating material can be suitably used for a shield layer. The volume resistivity of Example 1 was 5.8×10⁻⁵ Ω·cm, and indicated as a volume resistivity suitable for the conductive coating material used for the shield layer.

The volume resistivity was also measured for Examples 2 to 7 and Comparative Examples 1 to 6 in the same manner. The measured results are indicated in Table 1, and it was confirmed that in each of Examples 2 to 7, the volume resistivity is 10×10⁻⁵ Ω·cm or less, and thus the conductive coating material can be suitably used for the shield layer. On the other hand, in Comparative Examples 1 and 4, it was confirmed that the volume resistivity greatly exceeded 10×10⁻⁵ Ω·cm, and thus the conductive coating material is unsuitable to be used for the shield layer.

(2) Adhesion of Conductive Coating Material (Measurement of Shear Strength Before Solder Dip)

The shear strength was measured according to JIS K 6850:1999 as an evaluation of the adhesion between the shield layer and the surface of the package or the ground circuit. Specifically, a copper plate having a width of 25 mm, a length of 100 mm, and a thickness of 1.6 mm was coated with a conductive coating material in a region of 12.5 mm in length, and a copper plate having a width of 25 mm, a length of 100 mm, and a thickness of 1.6 mm was adhered onto the copper plate. Subsequently, the copper plates were heated at 80° C. for 60 minutes and further heated at 160° C. for 60 minutes such that the copper plates were adhered to each other. Next, an adhesive surface was pulled in parallel using a tensile strength tester (manufactured by Shimadzu Corporation, trade name “Autograph AGS-X”), and the maximum load at break was divided by the adhesion area so as to calculate the shear strength. When the shear strength is 3.0 MPa or more, it can be used without problems.

It was confirmed that the shear strengths of Examples 1 to 7 were all 3.0 MPa or more, and it can be suitable for the shield layer. On the other hand, it was found that in Comparative Example 5, the shear strength was less than 3.0 MPa, and the adhesion of the shield layer was not sufficient.

(3) Connection Stability Between Ground Circuit and Conductive Coating Material

As a model of an IC package, a chip sample C (1.0 cm×1.0 cm, thickness of 1.3 mm) made of a glass epoxy-based material (FR-5) and including circuits 21 to 26, which were formed of copper foil having a thickness of 35 μm by through-hole plating, in an inner layer as illustrated in FIG. 3 was used. The circuits 21, 22, and 23 are a part of one continuous circuit, and the circuits 24, 25, and 26 are a part of another one continuous circuit, but the circuits 21 to 23 and the circuits 24 to 26 are not connected. The circuits 22 and 25 have pad portions where the copper foil is partially exposed from the bottom of the chip sample at the positions of the arrows respectively, and the circuits 21 and 26 respectively have circuit end portions 27 and 28 exposed from both end surfaces of the chip sample.

A conductive coating material was sprayed on the surface of the chip sample C under the same spraying conditions as above and was hardened so as to form a shield layer (conductive coating film) 29 having a film thickness of about 30 μm. With this, the two pad portions were electrically connected via the conductive coating film 29 in contact with the circuit end portions 27 and 28. Then, a connection resistance value (R1) from the circuit 22 to the circuit 25 connected via the circuit 21, the circuit end portion 27, the conductive coating film 29, the circuit end portion 28, and the circuit 26, and a connection resistance value (R2) between optional two points on the surface of the conductive coating film 29 were measured. That is, R1 is a numerical value indicating the connection stability between the circuits 22 and 25 and the conductive coating film 29, and R2 is a numerical value indicating the resistance value of the conductive coating film 29 itself. Then, a ratio (R1/R2) of R1 to R2 was calculated. When R1/R2 is less than 1, it means that the connection stability between the ground circuit and the conductive coating film is excellent.

The measured results of the connection stability (R1/R2) are as indicated in Table 1, and it is confirmed that Examples 1 to 7 have the connection stability which is less than 1, and the connection stability is excellent. On the other hand, Comparative Examples 1 to 3 and 6 have the connection stability which greatly exceeds 1, and the connection stability was inferior.

TABLE 1

| | | Example | | | | | | | Comparative Example | | | | | |
|---|---|---|---|---|---|---|---|---|---|---|---|---|---|---|
| | | 1 | 2 | 3 | 4 | 5 | 6 | 7 | 1 | 2 | 3 | 4 | 5 | 6 |
| Solid epoxy resin | | 15 | 15 | 15 | 15 | 15 | 15 | 15 | 15 | 15 | 15 | 15 | 15 | 15 |
| (parts by mass) | | | | | | | | | | | | | | |
| Liquid epoxy resin | | 35 | 35 | 35 | 35 | 35 | 35 | 35 | 35 | 35 | 35 | 35 | 35 | 35 |
| (parts by mass) | | | | | | | | | | | | | | |
| Remarks | Glycidyl | 10 | 10 | 10 | 10 | 10 | 10 | 10 | 10 | 10 | 10 | 10 | 10 | 10 |
| | amine- | | | | | | | | | | | | | |
| | based | | | | | | | | | | | | | |
| | epoxy | | | | | | | | | | | | | |
| | resin | | | | | | | | | | | | | |
| | Glycidyl | 25 | 25 | 25 | 25 | 25 | 25 | 25 | 25 | 25 | 25 | 25 | 25 | 25 |
| | ether- | | | | | | | | | | | | | |
| | based | | | | | | | | | | | | | |
| | epoxy | | | | | | | | | | | | | |
| | resin | | | | | | | | | | | | | |
| (Meth)acrylate | | 50 | 50 | 50 | 50 | 50 | 50 | 50 | 50 | 50 | 50 | 50 | 50 | 50 |
| compound | | | | | | | | | | | | | | |
| (parts by mass) | | | | | | | | | | | | | | |
| Total amount of binder | | 100 | 100 | 100 | 100 | 100 | 100 | 100 | 100 | 100 | 100 | 100 | 100 | 100 |
| components | | | | | | | | | | | | | | |
| Hardener (parts by mass) | | 20 | 20 | 20 | 20 | 20 | 20 | 20 | 20 | 20 | 20 | 20 | 20 | 20 |
| Solvent (parts by mass) | | 280 | 280 | 280 | 570 | 160 | 280 | 280 | 280 | 280 | 280 | 280 | 280 | 280 |
| Metal | Sphere | 675 | 450 | 225 | 850 | 137.5 | — | — | 900 | 180 | 90 | 337.5 | 950 | — |
| particles | (reduced | | | | | | | | | | | | | |
| (parts by | powder) | | | | | | | | | | | | | |
| mass) | Sphere | — | — | — | — | — | 450 | — | — | — | — | — | — | — |
| | (atomized | | | | | | | | | | | | | |
| | powder) | | | | | | | | | | | | | |
| | Sphere | — | — | — | — | — | — | 450 | — | — | — | — | — | — |
| | (electrolytic | | | | | | | | | | | | | |
| | powder) | | | | | | | | | | | | | |
| | Flaky | 225 | 450 | 675 | 850 | 412.5 | 450 | 450 | — | 720 | 810 | 112.5 | 950 | 900 |
| | Total | 900 | 900 | 900 | 1700 | 550 | 900 | 900 | 900 | 900 | 900 | 450 | 1900 | — |

| | | | | | | | | | | | | | |
|---|---|---|---|---|---|---|---|---|---|---|---|---|---|
| Sphere:Flaky | 75:25 | 50:50 | 25:75 | 50:50 | 25:75 | 50:50 | 50:50 | 100:0 | 20:80 | 10:90 | 75:25 | 50:50 | 0:100 |
| Cone-plate rotary | 155 | 183 | 196 | 570 | 250 | 160 | 208 | 253 | 181 | 209 | 22 | 653 | 219 |
| viscometer (mPa · s) | | | | | | | | | | | | | |
| Volume resistivity | 7.9 | 5.8 | 5.8 | 5.7 | 8.5 | 9 | 5.5 | 12 | 6 | 5.6 | 12 | 9 | 8 |
| (×10⁻⁵ Ω · cm) | | | | | | | | | | | | | |
| Shear strength (MPa) | 4.5 | 4.5 | 4.7 | 3.5 | 4.7 | 4.6 | 4.3 | 4.5 | 4.6 | 4.7 | 5 | 2.5 | 4.7 |
| Connection stability | 0.72 | 0.59 | 0.34 | 0.81 | 0.85 | 0.43 | 0.88 | 2.57 | 13.5 | 14 | 0.6 | 0.95 | 5.3 |
| (R1/R2) | | | | | | | | | | | | | |

Priority is claimed on Japanese Patent Application No. 2016-139566, filed on Jul. 14, 2016, the content of which is incorporated herein by reference.

The foregoing description of specific embodiments of the present invention has been presented for the purpose of illustration. Those are not intended to be exhaustive or to limit the present invention as it is in the form described. It is apparent to those skilled in the art that numerous variations and modifications are possible in light of the above description.

### REFERENCE SIGNS LIST

A package individualized on substrate
B, B1, B2, and B9 individualized shielded package
C chip sample
1 substrate,
2 electronic part,
3 ground circuit pattern (copper foil),
4 sealing material,
shield layer (conductive coating film),
11 to 19 groove
21 to 26 circuit,
27, 28 circuit end portion,
29 shield layer (conductive coating film)

1-6. (canceled)

7. A conductive coating material comprising, at least:
(A) 100 parts by mass of binder component containing 5 to 30 parts by mass of solid epoxy resin which is a solid at normal temperature and 20 to 90 parts by mass of liquid epoxy resin which is a liquid at normal temperature in a range not exceeding 100 parts by mass in total;
(B) 500 to 1800 parts by mass of metal particles; and
(C) 0.3 to 40 parts by mass of hardener,
wherein the metal particles include (a) spherical metal particles and (b) flaky metal particles, and a mass ratio of (a) the spherical metal particles to (b) the flaky metal particles is 25:75 to 75:25 (in terms of (a):(b)), and
wherein a viscosity at a liquid temperature of 25° C. of the conductive coating material is 100 to 600 mPa·s when measured at rotation speed of 0.5 rpm with a cone-plate rotary viscometer.

8. The conductive coating material according to claim 7,
wherein the liquid epoxy resin contains 5 to 35 parts by mass of liquid glycidyl amine-based epoxy resin and 20 to 55 parts by mass of liquid glycidyl ether-based epoxy resin.

9. The conductive coating material according to claim 8,
wherein the liquid glycidyl amine-based liquid epoxy resin has 80 to 120 g/eq of epoxy equivalent and 1.5 Pa·s or less of viscosity, and the liquid glycidyl ether-based epoxy resin has 180 to 220 g/eq of epoxy equivalent and 6 Pa·s or less of viscosity.

10. The conductive coating material according to claim 7,
wherein the (A) binder component further contains a (meth)acrylate compound.

11. The conductive coating material according to claim 8,
wherein the (A) binder component further contains a (meth)acrylate compound.

12. The conductive coating material according to of claim 9,
wherein the (A) binder component further contains a (meth)acrylate compound.

13. The conductive coating material according to claim 7, which is used for shielding a package of an electronic part.

14. The conductive coating material according to claim 8, which is used for shielding a package of an electronic part.

15. The conductive coating material according to claim 9, which is used for shielding a package of an electronic part.

16. The conductive coating material according to claim 10, which is used for shielding a package of an electronic part.

17. A production method for a shielded package in which electronic parts are mounted on a substrate, and a package obtained by sealing the electronic parts with a sealing material is covered with a shield layer, the method comprising, at least:
a step of mounting a plurality of electronic parts on a substrate and sealing the electronic parts by filling the substrate with a sealing material and hardening the sealing material;
a step of forming a groove portion by cutting away the sealing material between the plurality of electronic parts and individualizing a package of each electronic part on the substrate by the groove portion;
a step of coating the conductive coating material according to claim 7 by spraying on a substrate on which the individualized package is formed;
a step of forming a shield layer by heating the substrate on which the conductive coating material is coated and hardening the conductive coating material; and
a step of obtaining an individualized shielded package by cutting the substrate, on which the shield layer is formed, along the groove portion.

18. A production method for a shielded package in which electronic parts are mounted on a substrate, and a package obtained by sealing the electronic parts with a sealing material is covered with a shield layer, the method comprising, at least:
a step of mounting a plurality of electronic parts on a substrate and sealing the electronic parts by filling the substrate with a sealing material and hardening the sealing material;
a step of forming a groove portion by cutting away the sealing material between the plurality of electronic parts and individualizing a package of each electronic part on the substrate by the groove portion;
a step of coating the conductive coating material according to claim 8 by spraying on a substrate on which the individualized package is formed;
a step of forming a shield layer by heating the substrate on which the conductive coating material is coated and hardening the conductive coating material; and
a step of obtaining an individualized shielded package by cutting the substrate, on which the shield layer is formed, along the groove portion.

19. A production method for a shielded package in which electronic parts are mounted on a substrate, and a package obtained by sealing the electronic parts with a sealing material is covered with a shield layer, the method comprising, at least:
a step of mounting a plurality of electronic parts on a substrate and sealing the electronic parts by filling the substrate with a sealing material and hardening the sealing material;
a step of forming a groove portion by cutting away the sealing material between the plurality of electronic parts and individualizing a package of each electronic part on the substrate by the groove portion;
a step of coating the conductive coating material according to claim 9 by spraying on a substrate on which the individualized package is formed;
a step of forming a shield layer by heating the substrate on which the conductive coating material is coated and hardening the conductive coating material; and
a step of obtaining an individualized shielded package by cutting the substrate, on which the shield layer is formed, along the groove portion.

20. A production method for a shielded package in which electronic parts are mounted on a substrate, and a package obtained by sealing the electronic parts with a sealing material is covered with a shield layer, the method comprising, at least:
a step of mounting a plurality of electronic parts on a substrate and sealing the electronic parts by filling the substrate with a sealing material and hardening the sealing material;
a step of forming a groove portion by cutting away the sealing material between the plurality of electronic parts and individualizing a package of each electronic part on the substrate by the groove portion;
a step of coating the conductive coating material according to claim 10 by spraying on a substrate on which the individualized package is formed;
a step of forming a shield layer by heating the substrate on which the conductive coating material is coated and hardening the conductive coating material; and
a step of obtaining an individualized shielded package by cutting the substrate, on which the shield layer is formed, along the groove portion.

21. A production method for a shielded package in which electronic parts are mounted on a substrate, and a package obtained by sealing the electronic parts with a sealing material is covered with a shield layer, the method comprising, at least:
a step of mounting a plurality of electronic parts on a substrate and sealing the electronic parts by filling the substrate with a sealing material and hardening the sealing material;
a step of forming a groove portion by cutting away the sealing material between the plurality of electronic parts and individualizing a package of each electronic part on the substrate by the groove portion;
a step of coating the conductive coating material according to claim 11 by spraying on a substrate on which the individualized package is formed;
a step of forming a shield layer by heating the substrate on which the conductive coating material is coated and hardening the conductive coating material; and
a step of obtaining an individualized shielded package by cutting the substrate, on which the shield layer is formed, along the groove portion.
